(19) United States
(12) Patent Application Publication
(10) Pub. No.: US 2025/0045492 A1
(43) Pub. Date: Feb. 6, 2025

(54) Agile Hardware Implementation System with Learning-Based Synthesis Assistance

(71) Applicant: Mitsubishi Electric Research Laboratories, Inc., Cambridge, MA (US)

(72) Inventors: Toshiaki KOIEK AKINO, Cambridge, MA (US); Rubel AHMED, Cambridge, MA (US)

(73) Assignee: Mitsubishi Electric Research Laboratories, Inc., Cambridge, MA (US)

(21) Appl. No.: 18/507,430

(22) Filed: Nov. 13, 2023

Related U.S. Application Data
(60) Provisional application No. 63/530,872, filed on Aug. 4, 2023.

(51) Int. Cl. G06F 30/27; G06F 8/40

(52) U.S. Cl. CPC G06F 30/27; G06F 8/40

(57) ABSTRACT

High-level synthesis (HLS) is a complex design flow that exploits the benefit of modern language features such as loops, inheritance, templates, etc. for rapid prototyping of hardware designs. Hardware engineers explore various design space parameters in a time-consuming trial-and-error approach to meet a target design specification. This invention provides a framework where machine learning methods are integrated with Bayesian optimization (BO) to accelerate hardware design in HLS. This tool is built around the context of HLS pragma exploration and kernel transformation. It can produce best set of pragma installments to determine parameters by optimizing on multi-objective functions, such as reduction of digital signal processor, flip-flop, look-up table, power consumption, and latency. The method uses classical deep neural network and quantum neural network for reinforcement meta learning to predict the synthesis characteristics and synthesizability under a given time budget. A large language model can also assist transpilation to modify the original codes so that the best tradeoff between hardware complexity, latency, and power consumption is realized.

### FIELD OF THE INVENTION

The present invention is related to a hardware implementation system of a low-power high-performance computer, more particularly to an agile prototyping system based on meta learning.

### BACKGROUND & PRIOR ART

To implement a computing method into hardware chips such as field-programmable gate-array (FPGA), a hardware description language (HDL) such as Verilog has been widely used in the past decades. However, the use of HDL is often not time-efficient as there are no unique ways to describe the HDL code from a particular computing method. In addition, the quality of resource and performance of the resulting hardware highly depends on the way how to describe the computing method in the HDL code. Therefore, developing hardware chips takes a long time to meet a specification such as power consumption, processing throughput, computing latency, and hardware footprint. To improve the development time scale, a high-level synthesis (HLS) design framework has been recently introduced. The HLS design can use a high-level language such as C/C++ and python to describe the computation method. It enables a rapid prototyping of the computation method by bypassing the HDL coding step. However, the HLS design comes with a vast array of design option for consideration such as target hardware device, resources, required precision level, required time for simulation, synthesis, co-simulation, etc. In addition, there could be many alternative implementations of a simple operation. In order to help hardware designers achieve a target design, high-level languages provide pragmas as guidelines for HLS systems. Proper use of pragmas can lead to a high quality, optimized and efficient hardware design. As pragma installation affects other design features such as resource usages, latency, target clock, etc., finding better Pareto front in a constrained development time is challenging in practice, especially due to a high degree of flexibility in pragma installment and kernel transpilations.

Most design space exploration (DSE) tools employ a heuristic approach to search for an optimal Pareto front in a shorter development time. Recently, learning-based DSE frameworks have been proposed. For example, Pyramid uses a machine learning (ML) model to estimate the maximum achievable throughput. A recent work predicts resource usages to synthesize a variety of convolutional neural networks (CNNs). Another tool Sherlock finds Pareto-optimal solutions by using active learning with a surrogate model. It shows the challenges of handling conflicting objectives in parameter optimization. However, a crucial factor missing here is the synthesizability within a given time budget. If the designs these tools suggest do not synthesize within a given time frame, the applicability of such tools remains limited.

Accordingly, there is a need to improve hardware design methodology for agile prototyping which considers multi-objective functions including latency, power consumption, precision, footprint size, speed, and throughput, under a limited development time budget.

### SUMMARY OF THE INVENTION

We first address the shortcomings of a conventional Bayesian optimization (BO): specifically, it has a slow convergence when the HLS tool cannot synthesize the design within a given time budget. In addition, our method considers alternative implementations of same kernel, using equivalent operations under a certain precision. With the ML-based failure/resource prediction in action, AutoHLS becomes an efficient design space exploration (DSE) framework for high-level designs. Key contributions are summarized below:
We propose AutoHLS framework to accelerate the DSE by using ML models.
This framework uses learning-based optimization framework based on Bayesian optimization and machine learning methods.
A novel DNN and a QNN model are employed to accurately predict synthesis failure and resource usages.
Pareto optimal DSE is realized by using multi-objective optimization framework to consider various hardware resource and performance metrics at the same time.
Reinforcement learning is used to accelerate DSE by using historical data exploration.
Automated installment of pragma directives is applied to modify the computing code.
Automated transpilation of the code is applied to explore different ways of coding.
The performance specification is adjusted by a user by natural language interface through the use of generative large language models (LLM).
Energy-efficient artificial intelligence (AI) models can be implemented by considering quantization, pruning, and distillation under the automated HLS framework.
We achieve up-to 70-fold speedup for HLS prototyping to find Preto front via kernel explorations.

We propose a machine learning framework that can accelerate DSE. We consider synthesis time as big hindrance to DSE, and overcome it by developing a time budget-centric ML method. Proposed method can reach optimal Pareto front solving a multi-objective resource optimization problem in the FPGA/ASIC resource space. A unique feature of our method is that it also includes kernel transpilations for resource efficient design. The evaluation on real-world DNN designs synthesis substantiates the efficacy of our framework in the HLS design flow.

Some embodiments use reinforcement learning to explore different high-level scripts from the scratch, and evaluated its feasibility/precision for the target operation. Green AI acceleration is realized in some embodiments, considering speed, accuracy, and power consumption. Integration of DNN/QNN into existing optimization methods such as evolutionary optimization is also realized by adjusting the behavior in meta-learning framework.

Some embodiments of the present invention can provide a system or method for the need for a framework that combines software and hardware implementation level optimization to improve the energy efficiency of sparse quantized deep neural networks (DNN). The proposed joint neural architecture optimization approach explores the best design in each paradigm, from Python simulation to hardware-FPGA implementation. As a result, it reaches the best power and area requirements in FPGA implementation. We evaluate our method on a real-time signal-processing DNN model and find that it achieves 1.7× improvements in power and 40× in area compared to the baseline implementation of the same model. Our findings demonstrate the effectiveness of the proposed framework in optimizing power and area requirements for DNNs, which is important for IoT and edge devices where resource constraints are acute.

Another embodiment of the present invention is based on recognition that High-level synthesis (HLS) is a design flow that leverages modern language features and flexibility, such as complex data structures, inheritance, templates, etc., to prototype hardware designs rapidly. Exploring various design space parameters can take much time and effort for hardware engineers to meet specific design specifications. This embodiment provides a novel framework called AutoHLS, which integrates a deep neural network (DNN) with Bayesian optimization (BO) to accelerate HLS hardware design optimization. Our tool focuses on HLS pragma exploration and operation transformation. It utilizes integrated DNNs to predict synthesizability within a given FPGA resource budget. We also investigate the potential of emerging quantum neural networks (QNNs) instead of classical DNNs for the AutoHLS pipeline. Our experimental results demonstrate up to a 70-fold speedup in exploration time.

According to some embodiments of the present investigation, a system is provided for electronic design automation. The system includes a memory storing instructions and a processor configured to execute steps of the instructions: transforming an application code according to a set of design specification and a set of design parameters; synthesizing the transformed application code according to a high-level synthesis method to generate a set of profiling reports for implementing on a target hardware device; predicting the set of profiling reports and synthesizability under a time budget based on a set of machine learning models; exploring the set of design parameters according to an agent policy based on the set of profiling reports; and generating a set of optimized hardware implementations according to a Pareto front selection.

Further, another embodiment of the present invention provides a computer-implemented method for electronic design automation. The computer-implemented method includes steps of: transforming an application code according to a set of design specification and a set of design parameters; synthesizing the transformed application code according to a high-level synthesis method to generate a set of profiling reports for implementing on a target hardware device; predicting the set of profiling reports and synthesizability under a time budget based on a set of machine learning models; exploring the set of design parameters according to an agent policy based on the set of profiling reports; and generating a set of optimized hardware implementations according to a Pareto front selection.

The present invention is based on a system for electronic design automation, using a memory storing instructions and a processor configured to execute steps of the instructions. The steps include: transforming an application code according to a set of design specification and a set of design parameters; synthesizing the transformed application code according to a high-level synthesis method to generate a set of profiling reports for implementing on a target hardware device; predicting the set of profiling reports and synthesizability under a time budget based on a set of machine learning models; exploring the set of design parameters according to an agent policy based on the set of profiling reports; and generating a set of optimized hardware implementations according to a Pareto front selection. The system can accelerate the design flow to find optimized hardware implementations by exploring design parameters subject to the application specification and a design time budget. The application code is transformed by a combination of code parsing, kernel transpilation, pragma installments, and so on. The application code is further modified by the kernel transpilation based on a combination of quantization, sparsification, approximation, splitting, pipelining, unrolling, inlining, distillation, and so on. To control the HLS behavior, the pragma installments are further employed by a combination of pragma type directives and pragma parameters. It explores the set of the pragma type including inline, interface, dataflow, pipeline, unroll, array partition, latency, alias, protocol, stream, and so on. The system uses the set of machine learning models based on a combination of support vector machine, logistic regression, ridge regression, deep neural networks, quantum neural networks, reinforcement learning, large language models, and so on. The set of machine learning models is trained with a dataset on hardware implementation, software implementation, algorithm implementation, artificial intelligence, digital signal processing, field-programmable gate-array prototyping, application-specific integrated circuit, microprocessor, liquid state computing, quantum computing, molecular computing, and so on. The agent policy performs decision making based on a combination of multi-objective reinforcement learning, meta-heuristic optimization, Bayesian optimization, the set of machine learning models, and so on.

The target hardware device includes field-programmable gate array, programmable logic array, application-specific integrated circuit, graphic processor unit, central processor unit, microprocessor, liquid state computer, quantum computer, molecular computer, and variants. The system finds a multi-objective solution over the Pareto front selection based the set of profiling reports. The set of profiling reports includes look-up table, flip-flop, digital signal processing, latency, power consumption, clock frequency, mean-square error, and so on. For some embodiments, the system further uses the large language models to adjust the agent policy controlled by a set of natural language prompt. It further enhances the usability and flexibility of the design automation system without requiring a domain specific knowledge to realize high-performance, high-speed, and low-power hardware prototypes in a shorter time of design pipeline.

### BRIEF DESCRIPTION OF THE DRAWING

The accompanying drawings, which are included to provide a further understanding of the invention, illustrate embodiments of the invention and together with the description, explaining the principle of the invention.

FIG. 1 shows an exemplar design flow for hardware implementations according to some embodiments;

FIG. 2 shows an exemplar design flow using ML-based forward model prediction according to some embodiments;

FIG. 3 shows an exemplar design flow using ML-based forward model prediction according to some embodiments;

FIG. 4 shows an exemplar design flow using ML-based forward model prediction and active learning according to some embodiments;

FIG. 5 shows an exemplar hardware chip based on FPGA framework according to some embodiments;

FIG. 6 shows an exemplar pragma installment and kernel transpilation according to some embodiments;

FIG. 7 shows an exemplar implementation result and Pareto front for processing time and look-up-table (LUT) counts, using different pragma installment and kernel transpilation according to some embodiments;

FIG. 8 shows an exemplar design automation system according to some embodiments;

FIG. 9 shows an exemplar computing method using different precision and quantization according to some embodiments;

FIG. 10 shows an exemplar method using deep neural network to assist design automation according to some embodiments;

FIG. 11 shows an exemplar method using quantum neural network to assist design automation according to some embodiments;

FIG. 12A shows an exemplar performance using different precision and quantization methods according to some embodiments;

FIG. 12B shows an exemplar performance using different time budgets and quantization methods according to some embodiments;

FIG. 13 shows an exemplar result using different machine learning methods to predict synthesis failure according to some embodiments;

FIG. 14 shows an exemplar result using different machine learning methods to predict LUT counts according to some embodiments;

FIG. 15 shows an exemplar result using the agile prototyping system according to some embodiments;

FIG. 16 shows an exemplar result using the agile prototyping system according to some embodiments;

FIG. 17 shows an exemplar method using model distillation for power-efficient AI computation according to some embodiments;

FIG. 18 shows an exemplar schematic of agile design automation for power-efficient AI models according to some embodiments;

FIG. 19A shows an exemplar result of agile design automation for power-efficient AI models according to some embodiments;

FIG. 19B shows an exemplar result of agile design automation for power-efficient AI models according to some embodiments;

FIG. 19C shows an exemplar result of agile design automation for power-efficient AI models according to some embodiments;

FIG. 19D shows an exemplar result of agile design automation for power-efficient AI models according to some embodiments;

FIG. 20 shows an exemplar design automation system using reinforcement learning and language interface according to some embodiments; and

FIG. 21 shows an exemplar schematic of the system configured with processor, memory and interface, according to some embodiments.

### DETAILED DESCRIPTION OF THE PREFERRED EMBODIMENTS

Various embodiments of the present invention are described hereafter with reference to the figures. It would be noted that the figures are not drawn to scale elements of similar structures or functions are represented by like reference numerals throughout the figures. It should be also noted that the figures are only intended to facilitate the description of specific embodiments of the invention. They are not intended as an exhaustive description of the invention or as a limitation on the scope of the invention. In addition, an aspect described in conjunction with a particular embodiment of the invention is not necessarily limited to that embodiment and can be practiced in any other embodiments of the invention.

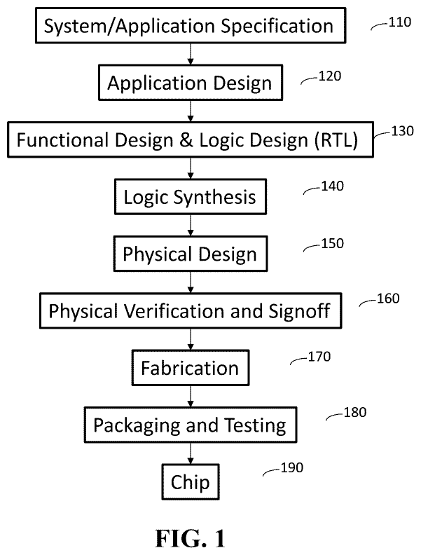

FIG. 1 shows an exemplar design flow for hardware implementations according to some embodiments. Hardware design usually starts with system specification 110 as a target and requirement such as clock frequency, latency, power consumption, accuracy, and footprints. Computing architecture is then designed 120 to meet the specification. Its functional design and logic design onto register-transistor logic (RTL) are then described 130. The RTL design is then synthesized 140 to gate logics. The gate logics are then physically designed 150 to be placed onto a plane. The design rule check (DRC) and other physical verification are conducted 160 before fabrication 170. The fabricated chiplet is then packaged and tested 180 before deploying as a custom computing chip 190. The target device (or target hardware device) includes field-programmable gate array, programmable logic array, application-specific integrated circuit, graphic processor unit, central processor unit, microprocessor, liquid state computer, quantum computer, molecular computer, and so on. Implementing a particular application code onto such a target hardware device is not straightforward because the device-specific characteristics and constraints exist such as power consumption, logic resource, processing speed and so on.

The typical workflow for hardware implementation takes a long time because there are a massibly large number of different designs to realize the system specification and a skilled designer uses heuristics from the experiences. In addition, the designed architecture, logic, and fabrication do not always meet the required quality of performance. Therefore, it typically requires a lot of trial-and-error iterations across the different steps of design workflow. The present invention provides a way to reduce the design time and effort by using AI-based assistance at different steps of design workflow in the system of electronic design automation (EDA).

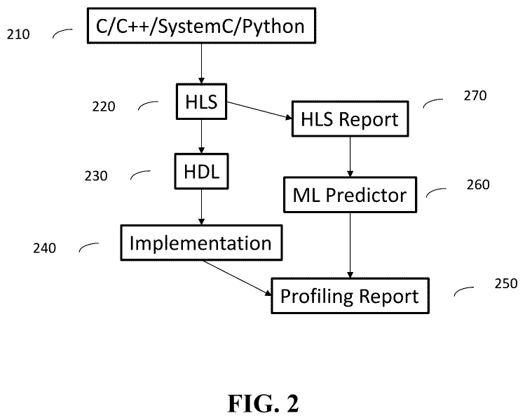

FIG. 2 shows an exemplar design flow using ML-based forward model prediction according to some embodiments. This embodiment provides the way to accelerate the design workflow by skipping RLT design 130 through the use of high-level synthesis (HLS) 220, which takes a high-level language 210 such as C/C++/SystemC/Python to automatically generate an hardwared-description language (HDL) 230 for implementation 240. The HLS is useful to keep the functional validity tested on the high-level language and simulations without violating the HDL consistency. However, the HDL synthesis takes a long time to generate the high-performance HDL codes, and the implementation results 250 are often unsatisfactory compared to the skilled HDL designers because of the massively large number of hyperparameters of HDL tool.

The present invention provides the way to improve the design workflow by using AI-based performance prediction 260, which estimates the real performance results before implementation from the HLS report 270. By using the AI-based prediction, the system can pre-adjust the important hyperparameters (or design parameters) such as pragma factors inserted in the source code (or application code) written in the high-level language. For example, those hyperparameters are optimized by meta-heuristic optimizers such as Bayesian optimization as an agent policy by observing the landscape of the predicted implementation results generated by the AI model, even without real implementation. Another example of the meta-heuristic optimizers includes differential evolution, evolutionary strategy, Nelder-Mead, genetic algorithms, simulated annealing, quantum annealing, swarm intelligence, and other variants.

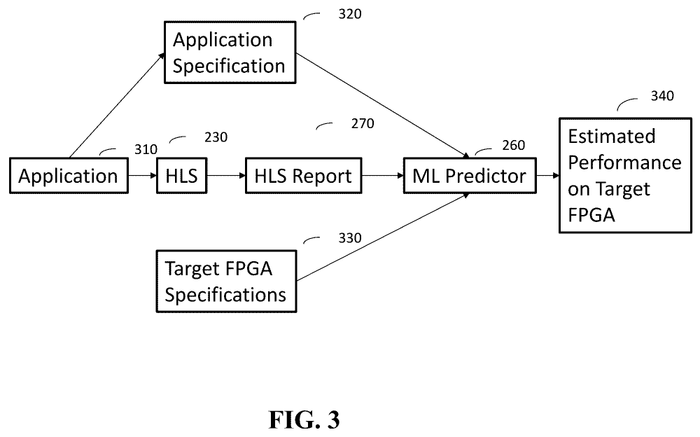

FIG. 3 shows an exemplar design flow using ML-based forward model prediction according to some embodiments. The AI-based predictor 260 takes additional information such as application characteristics 320 and target FPGA specifications 330 to predicted the performance on target FPGA device 340. The application 310 is written by the high-level languages 210. Besides the HLS report 270, application characteristics 320 and FPGA specifications 330 provide additional degree-of-freedom to improve the prediction accuracy across different target FPGA devices.

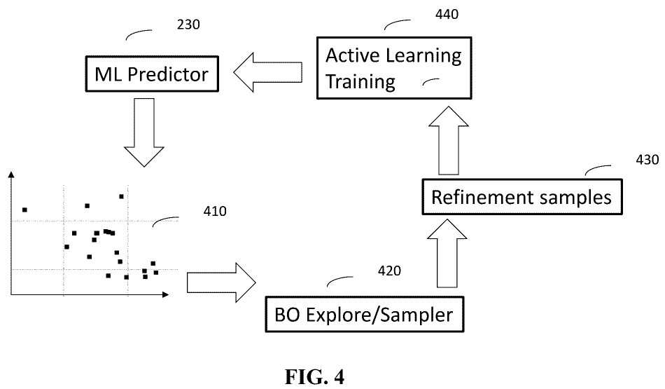

FIG. 4 shows an exemplar design flow using ML-based forward model prediction and active learning according to some embodiments. This embodiment uses an active learning to improve the accuracy of prediction. The AI-based predictor 230 generates performance estimates 410, from which some hopeful candidates of design parameters are sampled 420. The sampled parameters are then validated through the HLS tool to generate the true results of the performance in refined samples 430. Using the refined samples, the AI model 230 is trained 440 to adjust the behavior of the prediction towards real implementations gradually.

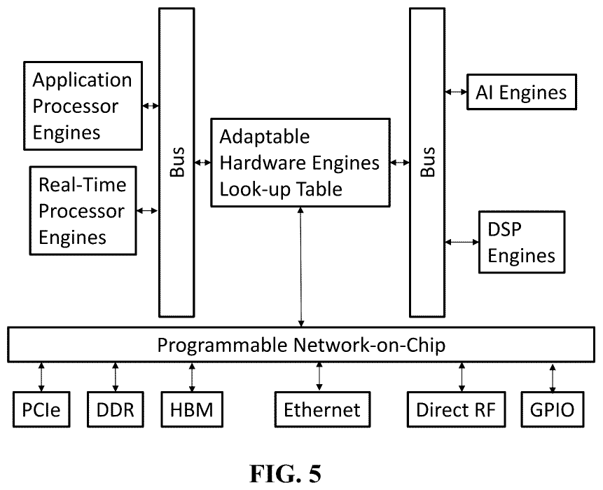

FIG. 5 shows an exemplar hardware chip based on FPGA framework according to some embodiments. The FPGA chip typically has network interfaces, computing engines, and adaptable hardware. The hardware design exploits the high degree of flexibility in adaptable hardware, which the computing functional behaviors are designed to utilize other built-in engines and interfaces. The hardware prototyping should consider the computational efficiency and power efficiency as well as the footprint efficiency at the same time. The HLS tools need to control various hyperparameters such as interface mechanism, parallelism, pipelining, and precision so that the application specification (or design specification) in quality of results is met. One such control method is realized by a pragma installment into a source code without breaking the computational functionality.

### Learning to Accelerate Design Space Exploration for HLS Designs

HLS is a widely used rapid design and prototyping method in industry and academia. Still, it poses several challenges for source code optimization due to the rich features of modern programming languages such as C/C++/Python. Careless optimization can result in inefficient and resource-hungry designs with high latency or, in some cases, loss of synthesizability under a reasonable FPGA resource budget. HLS compilers such as Vitis offer optimization tactics such as pragma directives and timing/closure analysis to tackle these issues which have spurred active research areas in design-space exploration (DSE) for HLS. Accelerated DSE is required since downstream tools used for RTL generation, such as Vitis, can take significant time to compile and report synthesis results. This limits the number of designs evaluated during DSE, resulting in sub-optimal solutions. Besides, the time required for RTL generation can increase the DSE time from hours to days, depending on the complexity of the design. The quest for faster and more efficient DSE in HLS has led to the development of machine learning (ML), artificial intelligence (AI) and analytical methods. In this context, an analytical approach leverages a Quality-of-Results (QoR) estimator to accelerate the DSE process. By statically analyzing code blocks and modeling latency and resource utilization, the QoR estimator enables DSE engine to explore the design space efficiently and converge to the Pareto front selection faster. Other methods use statistical, heuristic, ML, or meta-learning approaches to accelerate DSE. For instance, an ML model estimates the maximum achievable throughput. At the same time, it can predict resource usage for synthesizing computing methods such as convolutional neural networks. Active learning is also used with a surrogate model to find Pareto front, highlighting the challenges in handling conflicting objectives in parameter optimization. Some embodiments use a Bayesian Optimization (BO) framework, as a multi-objective optimization tool. BO is generally slow to find the Pareto front as the downstream HLS flow takes much time to generate QoR for each sample design point. Therefore, the present invention adds an early failure prediction network with the BO to accelerate the DSE, focusing on reducing the search space based on synthesizability constraints, such as FPGA footprints or synthesis time budget. The FPGA footprints include the block size of DSP engine, flip-flop (FF) gates, look-up table (LUT) size, and so on.

The present invention called AutoHLS optimizes the design by considering synthesizability constraints as a multi-objective optimization problem. AutoHLS efficiently determines loop unrolling factor, pipeline depth, array partition, etc., for pragma installments in order to optimize HLS designs considering signal DSP, FF, LUT, power consumption, and latency. Furthermore, AutoHLS also includes a step of kernel operations transformation to further optimize the designs. The pragma installments is realized by selection of pragma type directives and its pragma parameters. The pragma type includes inline, interface, dataflow, pipeline, unroll, array partition, latency, alias, protocol, stream, and so on to adjust the behavior of HLS tool.

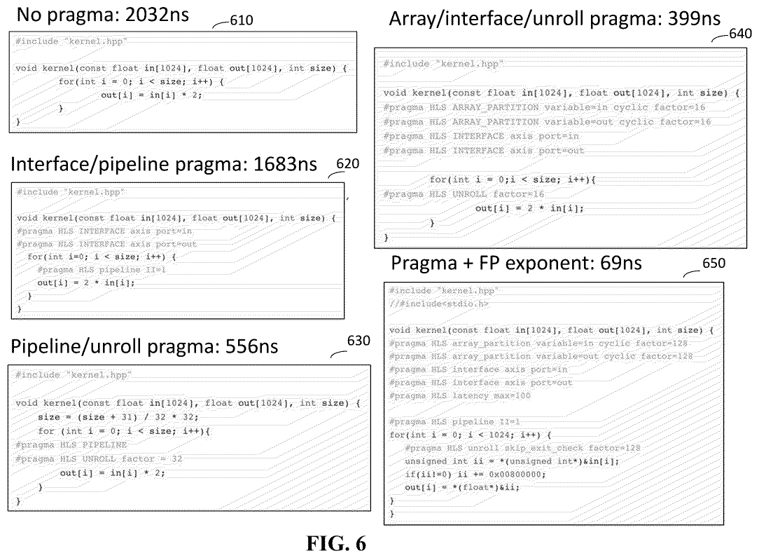

FIG. 6 shows an exemplar pragma installment and kernel transpilation according to some embodiments. In designing hardware in HLS, several critical factors must be considered, such as the target hardware device, available resources, required precision level, simulation, synthesis, co-simulation time, etc. In this regard, the source code 610 in FIG. 6 presents a regular array doubling kernel in C++ as an example. This source code has 2032 ns latency when HLS tries to synthesize in FPGA device without any pragma directives. However, HLS provides several alternative implementations, such as the codes 620, 630, 640, in FIG. 6, where different pragma directives are inserted. More specifically, the code 620 uses interface and pipeline pragma, the code 630 uses unroll pragma, and the code 640 uses array pragma to adjust the behavior of HLS, while the computing functionality is kept same in the FPGA chip. The code 620 can improve the latency from 2032 ns to 1683 ns, the code 630 can improve it to 556 ns, and the code 640 can further improve the latency to 399 ns. Another code 660 uses a kernel transformation, where a functionally equivalent exponent addition replaces the multiplication operation. As the computationally heavy multiplications can be removed, the latency can be drastically improved to 69 ns. However, deciding what kind of pragma directives and respective pragma parameters is not straightforward because of the large amount of design space. The kernel transpilation includes quantization, sparsification, approximation, splitting, pipelining, inlining, unrolling, and distillation to modify the application code. The transformed application code is functionally equivalent to the original application code but modified to be efficiently synthesized by the HLS tool.

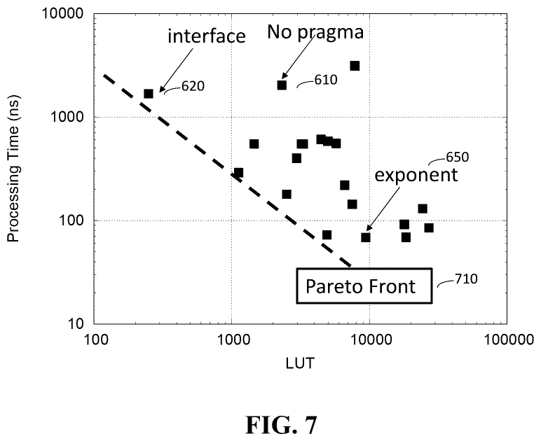

FIG. 7 shows an exemplar implementation result and Pareto front for processing time and look-up-table (LUT) counts, using different pragma installment and kernel transpilation according to some embodiments. The synthesis profiling results (or a set of profiling reports) over different pragma factors and kernel operation transforms show a tradeoff behavior in multi-objective optimization, where the reduction in LUT resources and runtime would compete as shown in the Pareto front curve 710 of FIG. 7. Nevertheless, due to the high degree of flexibility in pragma installment and kernel operation transforms, finding an optimal Pareto front in constrained development time remains challenging. In addition, the Pareto front landscape is more complicated when more QoR metrics are considered such as power consumption and throughput. The present invention provides a way to solve this issue.

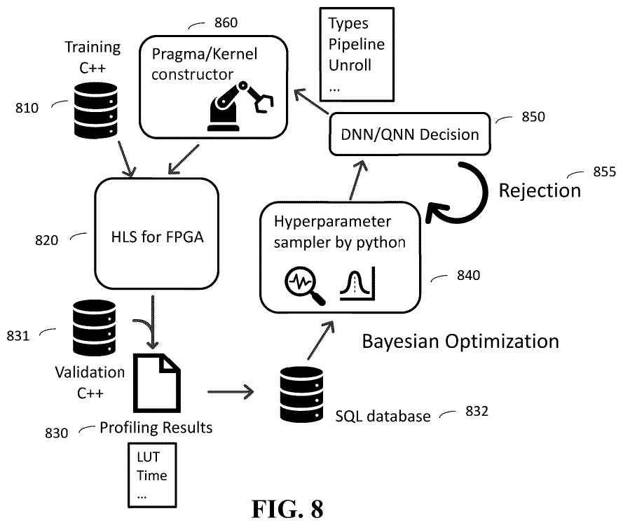

FIG. 8 shows an exemplar design automation system according to some embodiments. This embodiment takes an unoptimized kernel to efficiently explore different design alternatives so that design objectives meet the specification such as runtime, precision level, DSP, FF, LUT, etc., usage. It can discover an optimal set of pragma and kernel operation transforms with the help of an ML-based synthesizability prediction mechanism. The system takes the source code 810 in addition to the pragma directives and kernel transformation 860. HLS 820 on a target FPGA device tries to synthesize the source code to the FPGA implementation. The profiling results 830 are analyzed with other validation code 831, and stored in a database 832. The use of Bayesian optimization (BO) tries to find the best candidates to improve the results and provides samples of hyperparameters 840. Among the candidates suggested by the BO is then examined by the AI-based surrogate model 850, which predicts the QoR and synthesizability under the time budget. Until the AI-based surrogate model finds the synthesizable best candidates having high QoR, the candidate sampling by the BO will be rejected 855 to re-analyze and re-sample the candidates. After the best candidates are decided by the AI surrogate model, pragma insertion and kernel transforms are specified 860 to explore the next HLS synthesis. This design search exploration continues until the required budget of the design time is reached.

Pragma types and their parameters guide the HLS compiler toward optimal designs. For example, AutoHLS uses a categorical sampling of BO to decide the set of HLS pragma insertions P_{K}⊆EP, where P includes pipeline, unroll, interface, array, etc. Each HLS pragma P can have a set of pragma parameters A_{P}. Given a kernel K, AutoHLS decides a parameter set A_{K}⊆{A_{P}} for each HLS pragma P∈P_{K} in the selection, using BO sampling. For example, the parameters set of A_{K}={100, . . . , 128} is used for the pragma set P_{K}.

HLS synthesis tools often utilize high-cost resources, such as DSP blocks, to meet high throughput requirements, which may not be available for resource-constrained applications like edge/embedded devices. Therefore, considering alternative operations that can save resources at a potential cost of throughput or precision. For example, a regular multiplication kernel in source code 610 of FIG. 6 can be functionally equivalent to an exponent addition kernel in the code 650 of FIG. 6 for a floating-point operation when the multiplicand is a power-of-two (PoT) value. Furthermore, simplifications can be achieved by reducing bit-width precision and using fixed-point operations with bit-shifting. Given an HLS kernel K, kernel/operation transformation produces another kernel K such that the outputs from both kernels are approximately equivalent or exactly equivalent within a specified tolerance range. In addition, recent green ML models have also demonstrated that quantized DNNs, such as DeepShift, can outperform floating-point DNNs. Therefore, some embodiments use POT and additive-Power-of-Two (APOT) quantization for further optimization to realize power-efficient computing methods. For Bayesian optimization in DSE, hyperparameter optimization includes pragma directives such as unroll factor, pipeline instantiation interval, latency max and latency min.

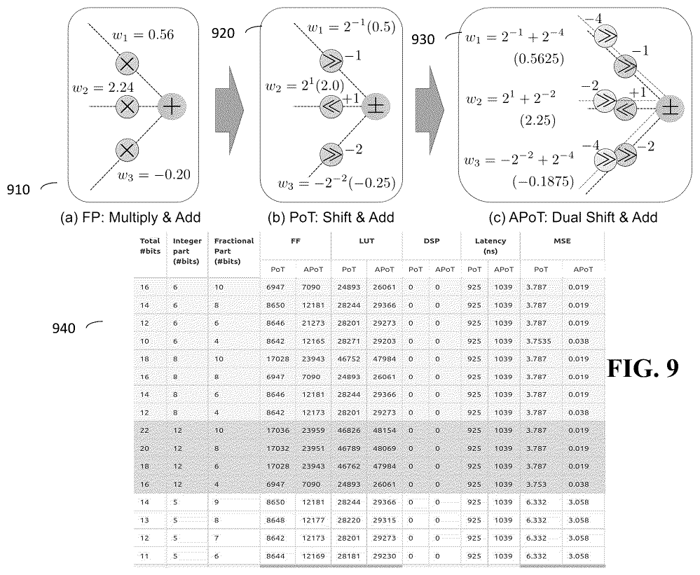

FIG. 9 shows an exemplar computing method using different precision and quantization according to some embodiments. FIG. 9 (a) uses a typical multiply-and-accumulation (MAC) operation 910 for floating-point precision, which requires high-speed and high-power DSP blocks in general. PoT quantization 920 can reduce the computational resources by approximating the multiplication operation through the use of shift-and-add operations, which can totally remove the high-power DSP blocks to execute multiplications. In order to reduce the precision error by POT quantization, APOT quantization uses multiple shift-and-add operations in sequence, which can still remove the requirement of DSP multipliers while keeping higher precision. The design space exploration chooses those different types of operations and precision factors including bitwidth for integer parts and fractional parts. Exploiting the different combinations of those operations 940, the QoR of implementation resources for FF, LUT, DSP, latency, and MSE can be adjusted.

AutoHLS explores both kernel and parameter space. Given a set of kernels K, an objective function, and an HLS design constraint, AutoHLS analyzes the kernels and returns a set of optimal synthesizable kernels for the given objectives that meet the design constraint. For the kernet transformation/transpilation, AutoHLS first parses the input C/C++/python kernels and constructs pragmas using the selected set P, which includes the pipeline, unroll, latency, array partition, etc. These kernels are then checked for feasibility before being synthesized.

For kernel profiling, after the synthesis step, the Quality of Results (QoR), kernel type, and pragma parameters are collected. The synthesis can be complete or fail for the given constraint such as HLS time budget. These data are utilized directly or indirectly in the objective function. To optimize the hyperparameters, AutoHLS adopts the BO method such as a tree-structured Parzen estimator (TPE) for DSE, which can handle multi-objective optimization. The TPE-based optimizer suggests a set of optimized design parameters from the parameter space based on an acquisition function for efficient Pareto optimization.

To decide the next design space exploration candidate, AutoHLS tool incorporates machine learning techniques to predict the synthesis failure and estimate the resource utilization of the designed kernel. Specifically, deep neural network (DNN) and quantum neural network (QNN) provide the failure prediction scores on each sample set generated by the BO. Based on the prediction results, the tool decides whether to synthesize or discard the kernel and move to the next one. This approach enables accelerated design space exploration and reduces the overall design time.

For analyzing the candidate samples, AutoHLS employs ML models to predict synthesis failure and estimate the resource profile of a design. These models, including classifiers and regression models, are trained on the already explored samples and assign a score to a new sample generated by BO. A decision is then made based on a threshold t. Finally, the sample is sent for synthesis only if it passes the decision maker.

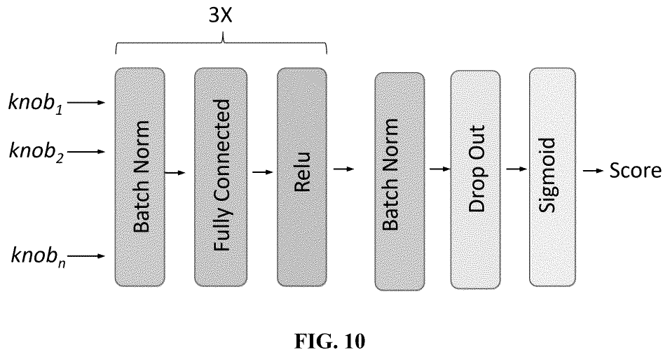

FIG. 10 shows an exemplar method using deep neural network to assist design automation according to some embodiments. This embodiment provides a DNN model for predicting a design's synthesizability score and resource usage. This exemplar model takes design parameters as input and consists of three repletions of batch normalization layers, a fully-connected layer, and a rectified linear unit (ReLU) activation. A batch normalization layer, a dropout, and a sigmoid are applied at the end in this exemplar DNN model. The DNN model typically has a relatively large number of trainable parameters such as 3000 and is designed to learn with limited training samples, which is essential in DSE due to the long synthesis time of HLS tools.

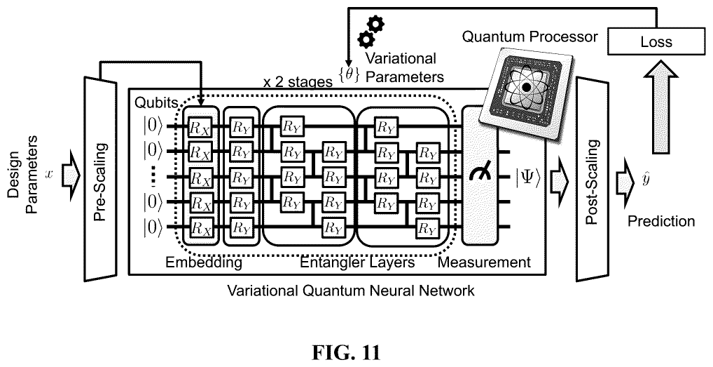

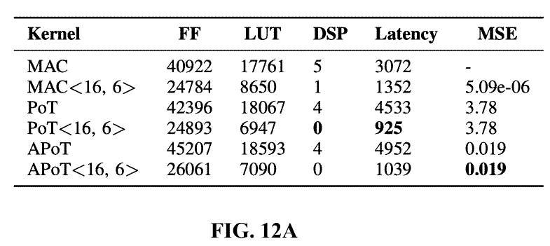

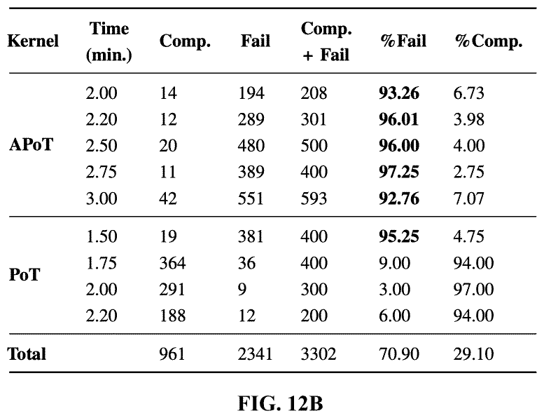

FIG. 11 shows an exemplar method using quantum neural network to assist design automation according to some embodiments. In this embodiment, the ML-based prediction methods for decision making use a quantum neural network (QNN) model. The recent advancements in quantum technology have led to the availability of high-qubit processors, such as the 433-qubit processors released by IBM in 2022. This has given rise to a new paradigm of ML models known as QNNs, which have the universal approximation property and are more compact than modern DNNs. In this embodiment, the QNNs are introduced for HLS acceleration. The exemplar QNN architecture shown in FIG. 12 has five quantum bits and only 54 trainable parameters, significantly fewer than the typical DNN models. This QNN model consists of an angle embedding layer, two-design entangling layers, and measurement layer as well as pre-scaling and post-scaling layers to predict the synthesizability and resource usages. For some embodiments, the QNN model includes: different embedding such as amplitude embedding, basis embedding, Mottonen state preparation and other variants; different entanglying layers such as tree tensor network (TTN), matrix product state (MPS), multiscale entanglement renormalizaton ansatz (MERA) and other variants; and different measurement layer such as Z-expectation, variance, state, probability, sample and other variants. The trainable variational parameters are trained to minimize the loss function through backprogation, meta-huristic optimization, or reinforcement learning.

Yet another embodiment, classical ML algorithms are used for resource prediction and decision making. The classical ML models include support vector machine (SVM), logistic regression (LR), linear regression, lasso, kernel ridge regression (KRR), Bayesian ridge regression (BRR) for failure prediction and hardware profile prediction.

For an exemplar system, the design automation is performed on a machine with an Intel Core i7-8700K CPU at 3.70 GHz and 64 GB of main memory, running on Ubuntu 20.04.5 LTS, to design on Xilinx ZCU104 board as a target FPGA, through Vitis HLS 2022.1 for kernel synthesis.

We validate the effectiveness of AutoHLS for the DSE of a convolutional neural network (CNN) block. We consider synthesis time t as a design resource budget or constraint. The CNN block comprises a window size L, an input channel Cᵢₙ, and an output channel Cₒᵤₜ, where the convolution operation involves element-wise multiplication and accumulation of the window and input channel elements. FIG. 12A shows an exemplar performance using different precision and quantization methods according to some embodiments. This table in FIG. 12A provides the QoR results and the area utilization of the convolutional kernel implementation, for the channel input Cᵢₙ=100, filter length L=7, channel output Cₒᵤₜ=106, and float32 as the datatype. The table shows different types of kernels, such as PoT<16, 6> and APoT<16, 6>, which are fixed-point data types specifying the total word bitwidth and fractional bitwidth respectively in the first and last arguments inside brackets. The results reveal kernel transformation significantly impacts the hardware footprint. However, kernel transformation may cause some loss in precision, which mean-square error (MSE) indicates. Additionally, the fixed-point POT has the lowest resource usage but higher MSE than APOT, which has better MSE but consumes more area than POT. Finding the optimal kernel requires DSE to determine the pragma and appropriate pragma parameters. To find the best hyperparameters, the BO method is integrated with AutoHLS having ML-based decision makers for further optimization.

Most ML models based on DNN use affine transform, which usually requires high-power MAC operations. To create hardware-friendly designs of green ML models, some embodiments use POT and APOT quantizations as kernel transformation schemes. A regular MAC with W as a weight of DNN, b as the bias, is expressed as y=Wx+b; the POT quantization of weight, W, u∈Z: W=±2^{u}; and APOT quantization of weight, W: W=±2^{u}±2^{v}, where u, v∈Z and v<u. Some embodiments further use additional integer factors more than 2 to achieve higher precision while keeping MAC-free operations.

FIG. 12B shows an exemplar performance using different time budgets and quantization methods according to some embodiments. This table in FIG. 12B presents the performance evaluation of BO on the exploration process. The column ‘Time’ indicates the synthesis time budget in minutes. The columns ‘Comp.’ and ‘Fail’ denote the number of samples for which the kernel synthesis succeeded and failed, respectively. The exploration involves 3302 designs, taking 4 to 6 minutes to complete, regardless of the synthesis status. However, most of the parameters suggested by the BO method failed to synthesize, resulting in a vain attempt to synthesize the wrong design. To address this problem, the present invention as known as AutoHLS leverages an early failure prediction mechanism with the ML-based decision maker.

In an exemplar validation, we generate 3302 convolution design samples with BO, and 961 of them are synthesizable within the given time budget. Each sample has five independent variables, one dependent variable, and a kernel identifier. We use all samples to train classification models and synthesizable samples to train regression models. Classification models predict the sample outcome and are used as early failure prediction models. Regression models predict FPGA resource usage. Our models converge quickly on the training data. It was demonstrated that our models can learn from a small number of training samples and achieve high accuracy on the test data.

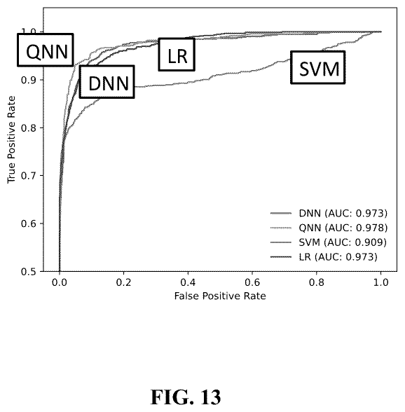

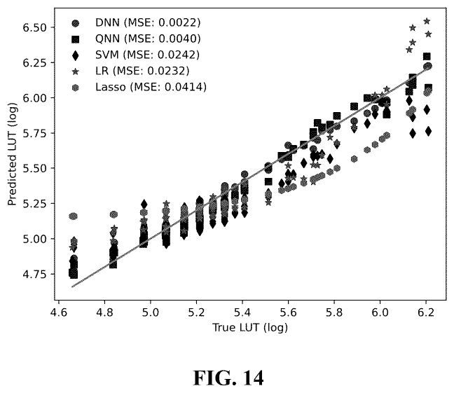

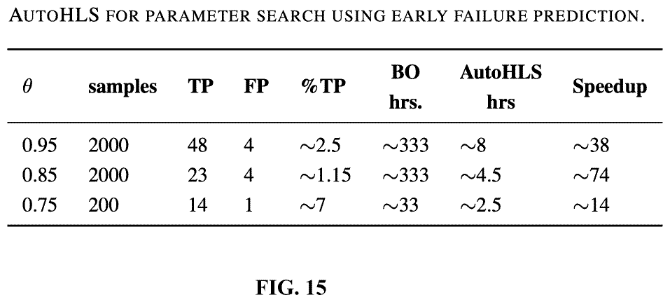

FIG. 13 shows an exemplar result using different machine learning methods to predict synthesis failure according to some embodiments. The performance with AI-assisted AutoHLS system is evaluated under various conditions. The results in FIG. 13 show high true positive (TP) rates in the receiver operating characteristic (ROC) curve. The AI models' robustness and generalization capabilities are also confirmed. They still achieve high true positive rates even when trained on only 5% of the samples. In particular, QNN-based prediction of synthesizability decisions achieves the highest area-under curve (AUC) scores in ROC curve in FIG. 13. FIG. 14 shows an exemplar result using different machine learning methods to predict LUT counts according to some embodiments. The AI-based prediction methods based on DNN and QNN models outperform classical regression methods such as SVM and LR. FIG. 15 shows an exemplar result using the agile prototyping system according to some embodiments. Regarding Pareto fronts, AutoHLS outperforms BO as highlighted in the dotted line in FIG. 15. The current invention can achieve lower LUT footprint and faster processing speed at the same time by considering the synthesis time budget.

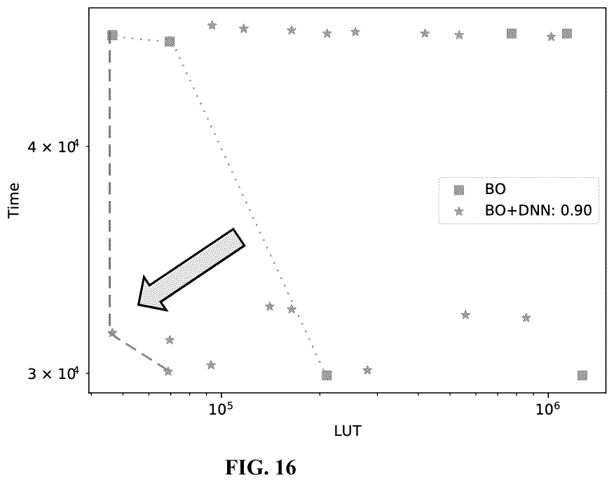

FIG. 16 shows an exemplar result using the agile prototyping system according to some embodiments. This table shows the effectiveness of the AI-based early failure prediction model by running a pragma parameter exploration for the APOT kernel. The estimated time for each design point synthesis is ten minutes. This table in FIG. 16 shows the results for different threshold values, demonstrating a speedup in synthesizable design exploration time ranging from 15 to 74 times faster when using the AI-based decision maker to predict synthesis failure. As validated, the system of the current inventing can provide an agile hardware prototyping method.

With the use of AI-based HLS behavior prediction and decision making mechanism, the AutoHLS can provide high generalizability towards unseen design space. Some embodiments provide an improvement for the generalizability by leveraging the vast amount of open-source FPGA synthesis data available e.g. in DB4HLS, which contains more than 100,000 design samples. The low false positive (FP) rate achieved by AutoHLS indicates that the machine learning models can learn effectively. Some embodiments consider synthesizability within a given time budget while other embodiments consider other metrics, such as DSP and clock cycle numbers. Due to the nature of HLS synthesis data, AutoHLS can learn from a small number of training data. In some embodiments, multi-objective reinforcement learning (MORL) methods are integrated with AutoHLS to enhance the robustness of this framework. For example, Pareto Q-learning method is used to optimize multiple factors such as LUT, MSE, FF, latency, throughput, and power consumption at the same time.

As described above, this embodiment can provide AutoHLS, a framework for accelerating DSE for HLS using DNN/QNN-enabled multi-objective BO. It addresses the shortcomings of BO in HLS optimization. Furthermore, it provides resource prediction mechanisms and faster exploration of the Pareto front. It demonstrates the effectiveness of this framework in achieving specific design goals through accelerated DSE and kernel operation transformation. Our experiments significantly speed up finding optimal FPGA design parameters for the CNN kernel.

### Joint Software-Hardware Design for Green AI

AI based on deep neural networks (DNN) has gained widespread popularity in various domains, including speech/audio, computer vision and signal processing. However, despite their high performance, DNN models are known to be energy-intensive. For instance, the energy required to train a large DNN model for natural language processing (NLP) can result in a significant carbon footprint, with an estimated 284 metric tons of CO2 emissions, equivalent to the lifetime emissions of five cars. This has led to the emergence of a new research direction called “green AI”, which aims to balance the tradeoff between power efficiency and inference accuracy. Green AI models have shown promise in accelerating DNN models, particularly on field-programmable gate array (FPGA) platforms.

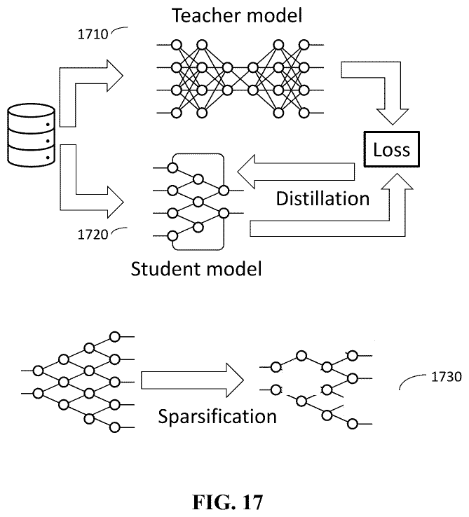

The energy consumption of AI models is primarily attributed to their architecture, particularly the computationally expensive vector-matrix multiplication and bias addition operations. FPGAs often use highly customized digital signal processing (DSP) blocks to implement these operations as shown in FIG. 5. Additionally, the size of training parameters, such as weights and biases, is another critical factor affecting energy consumption, with larger parameter sets requiring more energy. Therefore, various green AI models have been considered to address this challenge, including knowledge distillation, pruning, and quantization techniques as shown in FIG. 17, aimed at reducing the size of DNN models while maintaining high inference accuracy. FIG. 17 shows an exemplar method using model distillation for power-efficient AI computation according to some embodiments. These models are designed to downsize DNN models from a teacher model 1710 to a student model 1720 while maintaining high inference accuracy. Besides POT/APOT quantization, the model size such as kernel size/filter length, DNN layer depth, and neuron width size should be kept small for green AI. In addition, puring weights/neurons to remove redundant computations is often required to realize sparse DNN 1730 for reducing the power consumption. However, how to decide those hyperparameters is not straightforward to implement in the real hardware because of the huge design space. In addition, software-level optimization is not always leading to the hardware-level green AI. The current invention based on AutoHLS provides a way to resolve this issue by jointly optimizing the software-level architecture and hardware-level architecture designs.

Although sparse DNNs have lower computational complexities from a software perspective, their efficient hardware implementation might require significant resources. Therefore, an optimized design must consider the software and hardware requirements to minimize energy consumption. By jointly optimizing a DNN model from both domains, we should balance computational efficiency and energy consumption, resulting in a fast and energy-efficient implementation. The current invention provides a framework for optimizing green AI models from Python software implementation to FPGA hardware deployment to achieve energy-efficient designs. Some key characteristics are as follows:
The current invention provides a software-hardware design methodology for generating machine learning models optimized for energy-efficient hardware implementation.
We find that an optimal word size for fixed precision data that leads to compact circuitry.
The methodology enables the efficient implementation of sparse quantized DNN, which can significantly reduce the model's energy consumption.

One popular approach to optimize a DNN model is to reduce the precision of the weights and activations, reducing the amount of data that needs to be transferred and processed. This can be achieved through weight quantization and activation quantization techniques, such as Fixed-Point Quantization and Dynamic Fixed-Point Quantization. The Hardware-Aware Automated Quantization (HAQ) framework leverages reinforcement learning to determine the quantization policy for different neural networks and hardware architectures, effectively reducing latency and energy consumption with negligible loss of accuracy. For SqueezeNet, a set of modifications made to the network architecture to achieve energy goal includes aggressive channel reduction, separable 3×3 convolutions, and an element-wise addition skip connection, and optimization of the architecture by simulation, but no FPGA targeted optimization is discussed in prior arts. Another approach is to compress the size of the DNN model through techniques such as pruning, knowledge distillation, and parameter sharing. Pruning removes unimportant connections or filters in the network. At the same time, knowledge distillation trains a smaller network to mimic the behavior of a more extensive network.

Further, hardware-level optimizations have been extensively studied to improve the power efficiency of DNNs. These optimizations include designing specialized hardware accelerators and optimizing the hardware architecture, which can significantly reduce power consumption. Fixed-point arithmetic is often used instead of floating-point arithmetic to represent weights and activations in DNNs, which takes less energy for computation. Binary weights can also be restricted to only two possible values, which significantly reduces power consumption and hardware complexity by replacing multiply-accumulate (MAC) operations with simple additions. Optimization techniques can be applied to reduce power consumption in DNNs implemented on FPGAs, including software-level techniques like quantization and hardware-level techniques such as pipelining, parallelization, etc. In the current invention, the agile design system can optimize both software and hardware domains for power efficiency and computing precision.

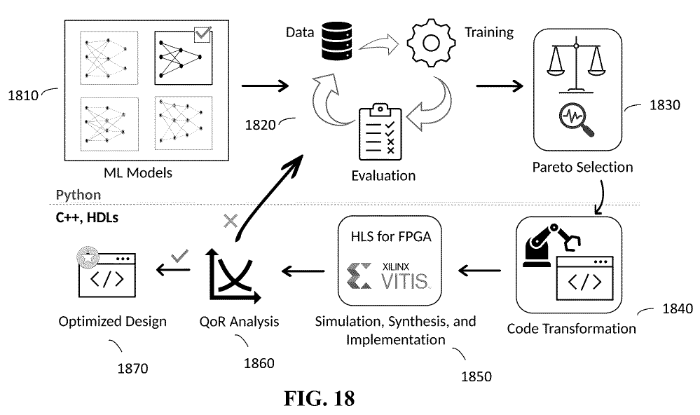

FIG. 18 shows an exemplar schematic of agile design automation for power-efficient AI models according to some embodiments. A general overview of the proposed approach is given in FIG. 18. The framework consists of Python simulation, C++ simulation, FPGA synthesis, and implementation for finding optimized RTL or FPGA implementation from a base ML model designed in Python. The general steps in this embodiment are as follows. The various ML models 1810 having different hyperparameter are evaluated 1820, and architecture selection 1830 are performed in the Pareto sense, and various optimization techniques are applied to maximize performance for the specific problem. Two crucial techniques used in this step are weight quantization and pruning. Weight quantization reduces the precision of neural network weights to reduce memory and computation requirements during inference. At the same time, pruning removes weights that have little effect on the output, reducing computation during inference. The optimized models or weights are the outcome of this step.

The complexity of a DNN model is often related to the number of non-zero (nnz) parameters associated with each ML model. For some embodiments, different weight quantization schemes are considered to optimize DNNs for efficient hardware implementation: e.g., no quantization, Power of Two (PoT) quantization, and Additive POT (APOT) quantization. A Pareto optimization approach selects the most power-efficient solutions based on trade-offs between accuracy and nnz. The Pareto front is identified, and the Pareto-optimal solutions providing the best performance for a given power budget are selected based on their trade-offs between accuracy and nnz in two steps.

The first step generates Pareto solutions for each quantization scheme by plotting accuracy against the nnz. The set of solutions with the best trade-off between accuracy and complexity is selected.

In the second step, the most optimized solutions are selected for RTL synthesis by comparing the Pareto fronts generated by different quantization schemes and refining them to obtain the final Pareto front.

It is possible that some solutions only varies on one axis or, in some case, even overlap. In that case, the most promising solution can be selected using the following rules. Let S be a set of Pareto solutions and nnz(s) be the number of non-zero parameters, nmse(s) denote the normalized mean squared error, P(s) denote the power consumption, C(s) denote the number of channels used, and H(s) denote the number of hidden layers in the solution set s. Select s* such that:
1. If solutions vary on nnz, but nmse is constant, pick one with the lowest nnz. s+=argmin {nnz(s): s∈S}.
2. If solutions vary on nmse, pick one with the lowest nmse. s*=argmin {nmse(s): s∈S}
3. The most power-efficient quantization will be selected if multiple solutions overlap with different quantizations. s*=argmin {P(s): s∈S}
4. If more than one solution overlaps with the same quantization, the solution with the lowest number of channels will be selected. s*=argmin {C(s): s∈S}
5. If multiple solutions overlap with the same quantization and the same number of channels, then the solution with the lowest number of hidden will be selected. s*=argmin {H(s): s∈S}

The aforementioned set of five rules will be henceforth referred to as “exclusion rules”, with subsequent sections referring to them by their assigned rule number as appropriate.

Transforming machine learning models from Python implementation to HDL code using HLS tool 1850 such as Vitis includes converting DNN layers, activation functions, and multi-input multi-output convolutions to C++ code while retaining the optimizations made in Python. To improve the HLS behavior, the pragma installments and code transpilation/transformation 1840 are performed in some embodiments. To ensure accuracy, the converted C++ code must undergo c-simulation. Some devices and FPGA-specific tasks can be performed in this code transformation 1840. The convolution function can also be optimized for performance and efficiency by exploring different quantization and sparsification.

In the Vitis HLS tool, the implementation step plays a crucial role in transforming the high-level C++ code into an optimized hardware implementation design 1870 that meets the specific constraints and requirements of the target FPGA device. This process accurately estimates the resources required for the design, including the number of logic cells, DSP blocks, memory blocks, and other FPGA resources. This step is critical for ensuring that the design meets power constraints. The implementation step generates the RTL HDL, which can program the FPGA to implement the hardware design. The HDL code can be written in VHDL or Verilog. An approximate power estimation can be obtained in this step.

Quality of Results (QoR) is a key metric to evaluate the overall quality of FPGA designs, considering factors such as performance, power consumption, area utilization, and timing. To facilitate a comparative analysis of QoR 1860, the design automation system uses various methods, such as timing analysis to check if the design meets the timing constraints, resource utilization analysis to ensure the design fits within the target FPGA device's capacity, and power analysis to measure the design's power consumption, which can be optimized for low power. These analyses can be performed at different stages of the design flow, including simulation, synthesis, and implementation.

In some embodiments, the method in the current invention can optimize jointly the software and hardware for a real-world low-latency, high-throughput CNN model. For example, the validation is conducted on a machine with an Intel Core i7-8700K CPU at 3.70 GHz, 64 GB main memory, and Ubuntu 20.04.5 LTS. The target FPGA synthesis board is Xilinx ZCU104, and Vitis HLS 2022.1 is used to synthesize the kernels.

We optimize a CNN-based Digital Pre-Distortion (DPD) model to mitigate distortion caused by power amplifier (PA) nonlinearities in digital communication systems. DNNs have shown promising results in mitigating nonlinear distortion in PAs. We consider a 1D CNN-based DPD system with two input and two output channels, which can have an arbitrary number of hidden channels. Our approach involves training a neural network with large input/output signal pairs to learn the PA's nonlinear behavior. Then, the neural network pre-distorts the input signal before amplification by the PA, canceling out the nonlinear distortions introduced by the amplifier. The CNN model has adjustable network configuration parameters such as kernel size, quantization type, number of hidden channels, number of hidden layers, and percentage of weights to be pruned.

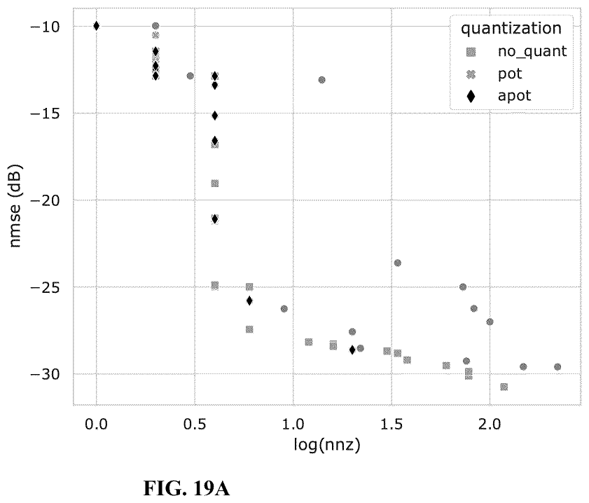

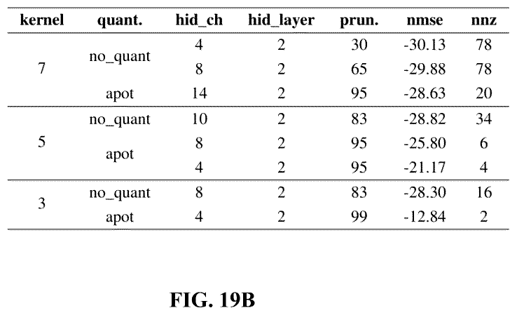

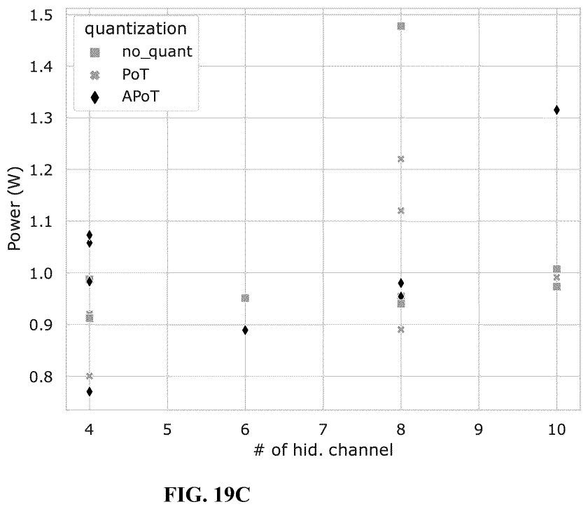

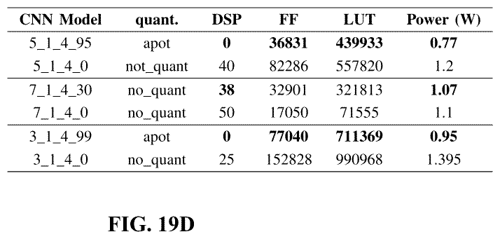

The optimization scope includes kernel size (e.g., different values: 3, 5, 7, and 11), quantization type (e.g., no quantization, POT, APOT), number of hidden layers (e.g., 2, 3, and 4), number of hidden channels (e.g., 2, 4, 6, 8, 10, 14, 16), and pruning percentage (e.g., 0, 30, 65, 83, 91, 95, 98, 99). A total of 840 samples are collected by sweeping those hyperparameters through all configurations, with metrics including normalized mean squared error (nmse) and the number of non-zero weights (nnz). The impact of each optimization technique on QoR is analyzed, including hidden channels, pruning percentage, nmse, and nnz. Pareto solutions are identified for each quantization type based on the results. Pareto optimal solutions can be obtained after optimizing the Python code for three types of quantization. FIG. 19A shows an exemplar result of agile design automation for power-efficient AI models according to some embodiments. Following the second step, the large search space reduced the number of solutions to 112 samples as a potential Pareto front candidates. Then, further exclusion rules are applied, resulting in the top several solutions. Eight of these top 50 solutions are presented in FIG. 19A. FIG. 19B shows an exemplar result of agile design automation for power-efficient AI models according to some embodiments.

Using fixed-precision representation in FPGA has several advantages, including reduced power consumption, increased speed of operations, and a more compact area requirement. Fixed-precision representation reduces the number of bits required to represent a floating point number, resulting in a smaller circuit size and lower power consumption. It also allows for better control over precision levels and value ranges, which can be optimized to suit specific application requirements. Some embodiments compare various inputs and arbitrary precision points to determine the optimal word size for fixed precision representation in DNN implementation.

Pragmas can substantially benefit HLS by reducing power consumption and optimizing memory access. They are commonly used for loop unrolling, data pipelining, array partitioning, etc., to minimize the number of operations and data movements in the design. By inserting pragmas in C++ source code of the CNN, DSP blocks and other resources can be conserved.

After determining the optimal word size and quantization type for a neural network, specific parameters, including kernel size, number of channels, number of layers, pruning percentage, and quantization type, need to be identified from Pareto solutions. Next, the system generates C++ code and synthesize it in Vitis HLS to estimate the FPGA footprint. FIG. 19C shows an exemplar result of agile design automation for power-efficient AI models according to some embodiments. The impact of the number of hidden channels on the power consumption and number of non-zero values (nnz) is analyzed as shown in FIG. 19C. Based on these observations, a hidden channel size can be optimized, resulting in Pareto solutions. Synthesis and implementation profiles of these solutions are presented in table of FIG. 19D. FIG. 19D shows an exemplar result of agile design automation for power-efficient AI models according to some embodiments.

PoT implementation of the kernel is generally more energy efficient. However, APOT can have better nmse and power consumption for a certain dataset and DNN models. Table in FIG. 19D shows the designs of the optimized hardware implementations against their non-optimized counterparts. In every row, the number of DSPs in the optimized CNN has been reduced because of the careful use of pragma and code transformation. Optimization techniques worked better in APOT quantizations but not in LUT and FF optimization in no-quantizations. The POT kernels are absent from the top Pareto solutions as we prioritized nmse over nnz. The PoTs have a higher chance of being on the Pareto fronts if we prioritize nnz.

As described above, this embodiment can provide a framework to address the challenge of hardware-software optimization of DNN models by presenting a design methodology for generating optimized hardware implementations by transpiring software code. By jointly optimizing the hardware and software components, it is possible to achieve a balance between computational efficiency and energy consumption, resulting in a system that is both fast and energy-efficient. The contributions of the framework include saving critical circuit resources and efforts spent in discovering multiple designs for rapid hardware prototyping and enabling the efficient implementation of green AI models.

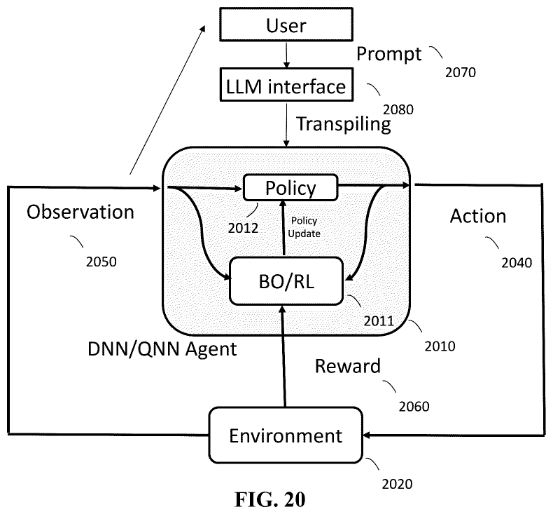

For some embodiments, the system uses reinforcement learning framework as shown in FIG. 20. FIG. 20 shows an exemplar design automation system using reinforcement learning and language interface according to some embodiments. The agent 2010 uses either classical deep neural network (DNN) or quantum neural network (QNN) models to adapt the DSE policy 2012 so that the HLS synthesis is accelerated under a time budget. The DNN/QNN agent takes an observation 2050 of the environment 2020 to adjust the action 2040 to maximize the reward 2060. For example, the environment 2020 includes the HLS synthesis, the observation 2050 includes the QoR reports of the hardware synthesis, and the action 2040 includes pragma installment and code transpiration for adjusting the pipelining, unrolling, quantization, and so on to optimize the latency, hardware footprint, power consumption, and throughput of the hardware chiplet. The reward 2060 includes improvement scores of hardware implementation in QoR, for example. For some embodiments, the large language model (LLM) 2080 such as ChatGPT and Llama finetuned with coding analysis is used as a user interface so that the transpilation policy is modified by natural language instruction with a user prompt 2070. For example, the LLM takes the user's prompt such as “modify the code to reduce the latency of the synthesized hardware”. The LLM 2080 tries to suggest the policy of transpilation to convert the original code based on the prompt 2070 so that the requested modification is applied. The LLM can be fine-tuned in active learning or pre-trained with massive public dataset of hardware implementation samples, e.g., in GitHub. Such dataset includes code samples and tricks for hardware implementation, software implementation, algorithm implementation, artificial intelligence (AI), digital signal processing (DSP), field-programmable gate-array (FPGA) prototyping, application-specific integrated circuit (ASIC), microprocessor, liquid state computing, quantum computing, molecular computing, and so on. It can explore different ways of computing methods with pipelining, parallelizing, quantizing, nesting, etc. For some embodiments, the original code is also parsed before feeding into LLM. For example, C/C++ code parsing with Clang format can generate unified extensible markup language (XML) formats to be analyzed by LLM. With the transpilation and HLS automation, the system can avoid further operation check after hardware implementation, resulting into an agile prototyping.

The system can be also used in different synthesis steps such as logic synthesis, physical design, and fabrication as shown in FIG. 1. It can be either forward modeling in FIG. 2, reinforcement learning in FIG. 3, or active learning in FIG. 4.

### Exemplar System

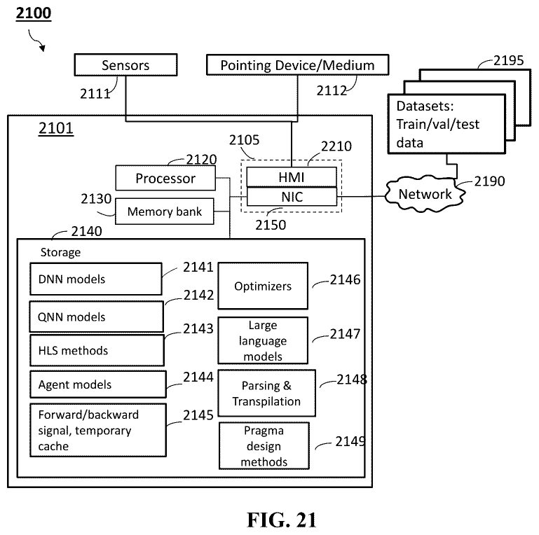

FIG. 21 shows an exemplar schematic of the system configured with processor, memory and interface, according to some embodiments. Specifically, FIG. 21 is a block diagram illustrating an example of a system for agile hardware implementation with AI-based synthesis assistance. The system 2100 includes a device 2101, having a set of interfaces and data links 2105 configured to receive and send signals, at least one processor 2120, a memory (or a set of memory banks) 2130 and a storage 2140. The processor 2120 performs, in connection with the memory 2130, computer-executable programs and algorithms stored in the memory 2130 and the storage 2140. The set of interfaces and data links 2105 includes a human-machine interface (HMI) 2110 and a network interface controller 2150. The processor 2120 can perform the computer-executable programs and algorithms in connection with the memory 2130 that uploads the computing instructions, computer-executable programs, and algorithms from the storage 2140. The instructions, computer-executable programs, and algorithms stored in the storage 2140 use deep neural networks (DNNs) 2141, quantum neural networks (QNNs) 2142, high-level synthesis (HLS) 2143, reinforcement learning agent policy 2144, forward-pass signals/backward-pass gradients and other temporary caches 2145, optimizers 2146, large language models (LLMs) 2147, code parsing and transpilation 2148, and pragma design methods 2149. The processor executes a design space exploration (DSE) to optimize hardware hyperparameters such as pipelining, unrolling, bitwidth, quantization method, interface and so on through analysis of the set of datasets by using optimizers, agent, and DNN/QNN models. LLMs are used to adjust the code transpilation methods by analyzing the natural language to control the quality of results for multi-objective optimization, e.g., lower LUT/FF/DSP footprint, lower power consumption, higher clock frequency, higher throughput, shorter latency, and so on.

The processor 2120 is configured to, in connection with the interface and the memory banks 2105, submit the signals and the datasets 2195 into the DNN blocks 2141 and QNN blocks 2143 to predict the resource usage and synthesizability under a time budget for assisting the HLS method 2143 via agent policy 2144. The optimizer 2146 includes Nelder-Mead, stochastic gradient, and Bayesian optimization. The processor 2120 further performs: configuring the DNNs 2141; calculating a loss function by forward-propagating the datasets 2195; backward-propagating a gradient of the loss function with respect to the trainable parameters across the DNNs 2141 to update the trainable parameters with optimization methods 2146. The system uses several DNN models 2141 and QNN models 2142 to establish agent models 2144, as well as LLM models 2147 for natural language interface. Code parsing and transpilation methods 2148 are stored in a memory. An automated pragma installment and modification methods are executed to optimize the hardware implementation through HLS methods 2143. The system 2100 receives signals from a set of sensors 2111 via a network 2190 and the set of interfaces and data links 2105, as well as other interface modules such as pointing device/medium 2112.

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

Also, the embodiments of the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. A system for electronic design automation, comprising a memory storing instructions and a processor configured to execute steps of the instructions:
transforming an application code according to a set of design specification and a set of design parameters;
synthesizing the transformed application code according to a high-level synthesis method to generate a set of profiling reports for implementing on a target hardware device;
predicting the set of profiling reports and synthesizability under a time budget based on a set of machine learning models;
exploring the set of design parameters according to an agent policy based on the set of profiling reports; and
generating a set of optimized hardware implementations according to a Pareto front selection.

2. The system of claim 1, wherein the transforming further comprises a combination of code parsing, kernel transpilation, pragma installments, and variants thereof.

3. The system of claim 2, wherein the kernel transpilation further comprises a combination of quantization, sparsification, approximation, splitting, pipelining, unrolling, inlining, distillation, and variants thereof.

4. The system of claim 2, wherein the pragma installments further comprise a combination of pragma type directives and pragma parameters, wherein the pragma type includes inline, interface, dataflow, pipeline, unroll, array partition, latency, alias, protocol, stream, and variants thereof.

5. The system of claim 1, wherein the set of machine learning models comprises a combination of support vector machine, logistic regression, ridge regression, deep neural networks, quantum neural networks, reinforcement learning, large language models, and variants thereof.

6. The system of claim 1, wherein the set of machine learning models is trained with a dataset on hardware implementation, software implementation, algorithm implementation, artificial intelligence, digital signal processing, field-programmable gate-array prototyping, application-specific integrated circuit, microprocessor, liquid state computing, quantum computing, molecular computing, and variants thereof.

7. The system of claim 1, wherein the agent policy comprises decision making based on a combination of multi-objective reinforcement learning, meta-heuristic optimization, Bayesian optimization, and the set of machine learning models.

8. The system of claim 1, wherein the target hardware device is a combination of field-programmable gate array, programmable logic array, application-specific integrated circuit, graphic processor unit, central processor unit, microprocessor, liquid state computer, quantum computer, molecular computer, and variants thereof.

9. The system of claim 1, wherein the Pareto front selection is based the set of profiling reports, wherein the set of profiling reports further comprises a combination of look-up table, flip-flop, digital signal processing, latency, power consumption, clock frequency, mean-square error, and variants thereof.

10. The system of claim 5, where in the large language models adjust the agent policy controlled by a set of natural language prompt.

11. A computer-implemented method for electronic design automation comprising steps of:
transforming an application code according to a set of design specification and a set of design parameters;
synthesizing the transformed application code according to a high-level synthesis method to generate a set of profiling reports for implementing on a target hardware device;
predicting the set of profiling reports and synthesizability under a time budget based on a set of machine learning models;
exploring the set of design parameters according to an agent policy based on the set of profiling reports; and
generating a set of optimized hardware implementations according to a Pareto front selection.

12. The computer-implemented method of claim 11, wherein the transforming further comprises a combination of code parsing, kernel transpilation, pragma installments, and variants thereof.

13. The computer-implemented method of claim 12, wherein the kernel transpilation further comprises a combination of quantization, sparsification, approximation, splitting, pipelining, unrolling, inlining, distillation, and variants thereof.

14. The computer-implemented method of claim 12, wherein the pragma installments further comprise a combination of pragma type directives and pragma parameters, wherein the pragma type includes inline, interface, dataflow, pipeline, unroll, array partition, latency, alias, protocol, stream, and variants thereof.

15. The computer-implemented method of claim 11, wherein the set of machine learning models comprises a combination of support vector machine, logistic regression, ridge regression, deep neural networks, quantum neural networks, reinforcement learning, large language models, and variants thereof.

16. The computer-implemented method of claim 11, wherein the set of machine learning models is trained with a dataset on hardware implementation, software implementation, algorithm implementation, artificial intelligence, digital signal processing, field-programmable gate-array prototyping, application-specific integrated circuit, microprocessor, liquid state computing, quantum computing, molecular computing, and variants thereof.

17. The computer-implemented method of claim 11, wherein the agent policy comprises decision making based on a combination of multi-objective reinforcement learning, meta-heuristic optimization, Bayesian optimization, and the set of machine learning models.

18. The computer-implemented method of claim 11, wherein the target hardware device is a combination of field-programmable gate array, programmable logic array, application-specific integrated circuit, graphic processor unit, central processor unit, microprocessor, liquid state computer, quantum computer molecular computer, and variants thereof.

19. The computer-implemented method of claim 11, wherein the Pareto front selection is based the set of profiling reports, wherein the set of profiling reports further comprises a combination of look-up table, flip-flop, digital signal processing, latency, power consumption, clock frequency, mean-square error, and variants thereof.

20. The computer-implemented method of claim 15, where in the large language models adjust the agent policy controlled by a set of natural language prompt.
